(19) United States
(12) Patent Application Publication
(10) Pub. No.: US 2026/0255626 A1
(43) Pub. Date: Aug. 27, 2026

(54) HIGH ELECTRON MOBILITY TRANSISTOR

(71) Applicant: SUMITOMO ELECTRIC INDUSTRIES, LTD., Osaka (JP)

(72) Inventor: Junji KOTANI, Osaka (JP)

(21) Appl. No.: 19/530,984

(22) Filed: Feb. 5, 2026

(30) Foreign Application Priority Data
Feb. 25, 2025 (JP) 2025-027984

(51) Int. Cl. H10D 30/47; H10D 62/85

(52) U.S. Cl. CPC H10D 30/475; H10D 62/8503

(57) ABSTRACT

A high electron mobility transistor includes: a first barrier layer having a first main surface and containing an impurity; a channel layer having a second main surface facing the first main surface and a third main surface opposite to the second main surface; and a second barrier layer having a fourth main surface facing the third main surface. The first main surface has a nitrogen polarity. The channel layer has a first average impurity concentration of the impurity and a first band gap. The second barrier layer has a second average impurity concentration of the impurity higher than the first average impurity concentration in the channel layer, and has a second band gap greater than the first band gap of the channel layer.

### CROSS-REFERENCE TO RELATED APPLICATION

The present application claims priority under 35 U.S.C. §119 to Japanese Patent Application No. 2025-027984, filed February 25, 2025, the contents of which are incorporated herein by reference in their entireties.

### BACKGROUND OF THE INVENTION

### Field of the Invention

The present disclosure relates to a high electron mobility transistor.

### Description of the Related Art

Conventionally, there has been proposed a high electron mobility transistor (HEMT) including a buffer layer and a channel layer whose upper surfaces have nitrogen polarity (for example, Japanese Patent Application Laid-Open Publication No. 2019-192795 and U.S. Patent Application Publication No. 2020/0273974).

### SUMMARY OF THE INVENTION

The high electron mobility transistor of the present disclosure includes a first barrier layer having a first main surface and containing an impurity, a channel layer having a second main surface facing the first main surface and a third main surface opposite to the second main surface, and a second barrier layer having a fourth main surface facing the third main surface, wherein the first main surface has a nitrogen polarity, the channel layer has a first average impurity concentration of the impurity and a first band gap, and the second barrier layer has a second average impurity concentration of the impurity higher than the first average impurity concentration in the channel layer, and has a second band gap greater than the first band gap of the channel layer.

### BRIEF DESCRIPTION OF THE DRAWINGS

FIG. 1 is a cross-sectional view showing a high electron mobility transistor according to a first embodiment;

FIG. 2 is a cross-sectional view showing a high electron mobility transistor according to a reference example;

FIG. 3 is a diagram showing a band structure of the high electron mobility transistor according to the reference example;

FIG. 4 is a diagram showing a band structure of the high electron mobility transistor according to the first embodiment;

FIG. 5 is a cross-sectional view showing a model used for simulation;

FIG. 6 is a graph showing results of the simulation;

FIG. 7 is a cross-sectional view showing a high electron mobility transistor according to a second embodiment; and

FIG. 8 is a cross-sectional view showing a high electron mobility transistor according to a third embodiment.

### DETAILED DESCRIPTION OF THE DISCLOSURE

In recent years, there has been an increasing demand for further improvement of electron mobility.

An object of the present disclosure is to provide a high electron mobility transistor capable of improving electron mobility.

According to the present disclosure, electron mobility can be improved.

### Description of Embodiments of the Disclosure

First, embodiments of the disclosure will be described in a list form.

[1] A high electron mobility transistor according to one aspect of the present disclosure includes a first barrier layer having a first main surface and containing an impurity, a channel layer having a second main surface facing the first main surface and a third main surface opposite to the second main surface, and a second barrier layer having a fourth main surface facing the third main surface, wherein the first main surface has a nitrogen polarity, the channel layer has a first average impurity concentration of the impurity and a first band gap, and the second barrier layer has a second average impurity concentration of the impurity higher than the first average impurity concentration in the channel layer, and has a second band gap greater than the first band gap of the channel layer.

Since the second barrier layer has the second average impurity concentration higher than the first average impurity concentration and the second band gap greater than the first band gap, the conduction band minimum is higher in the second barrier layer than in the channel layer, and becomes lower in the second barrier layer as the distance from the fourth main surface increases. This minimizes penetration of the electron wave function into the barrier layer, thereby enhancing the electron mobility.

[2] In [1], the first barrier layer may contain aluminum gallium nitride, and the channel layer may contain gallium nitride. This facilitates epitaxial growth of the barrier layer and the channel layer, and achievement of stable characteristics.

[3] In [2], the second barrier layer may contain aluminum gallium nitride. This facilitates epitaxial growth of a cap layer, and achievement of stable characteristics.

[4] In [3], a ratio of aluminum among Group III elements contained in the second barrier layer may be 15 at% or greater and 55 at% or less, and the second average impurity concentration may be 1×10¹⁷ cm⁻³ or greater and 1×10²⁰ cm⁻³ or less. The second average impurity concentration being 1×10¹⁷ cm⁻³ or greater facilitates the electron concentration to be high in the channel layer. In addition, the second average impurity concentration being 1×10²⁰ cm⁻³ or less can prevent the threshold voltage from being excessively deep.

[5] In any of [1] to [4], the first average impurity concentration may be less than 1×10¹⁷ cm⁻³. In this case, it is possible to inhibit impurity scattering in the channel layer.

[6] In any of [1] to [5], the second barrier layer may have a fifth main surface opposite to the fourth main surface, and an impurity concentration of the impurity in the fifth main surface may be lower than an impurity concentration of the impurity in the fourth main surface. This can facilitate reduction of gate leakage.

[7] In any of [1] to [6], the high electron mobility transistor may further include a source electrode, a gate electrode, and a drain electrode above the second barrier layer, and a recess may be formed in the second barrier layer such that the recess overlaps the gate electrode in a plan view perpendicular to the first main surface. In this case, it is possible to prevent the threshold voltage from being excessively deep.

[8] In any of [1] to [6], the high electron mobility transistor may further include a source electrode, a gate electrode, and a drain electrode above the second barrier layer, the second barrier layer may include a first region overlapping the gate electrode in a plan view, a second region closer to the source electrode than the first region is, and a third region closer to the drain electrode than the first region is, the first region may have a third average impurity concentration, the second region may have a fourth average impurity concentration higher than the third average impurity concentration, and the third region may have a fifth average impurity concentration higher than the third average impurity concentration. Also in this case, it is possible to prevent the threshold voltage from being excessively deep.

[9] In any of [1] to [8], the high electron mobility transistor may have a band structure in which a quantum well formed by a first potential barrier and a second potential barrier is located between the first barrier layer and the second barrier layer in a layer lamination direction. This minimizes penetration of the electron wave function into the first barrier layer beyond the first potential barrier, and inhibits electrons from being scattered by impurities, which tend to improve the electron mobility.

### Details of Embodiments of the Present Disclosure

Embodiments of the present disclosure will be described in detail below, but the present disclosure is not limited thereto. It should be noted that in the specification and the drawings, components having substantially the same functional configurations are denoted by the same reference numerals, thereby omitting redundant descriptions. In the present disclosure, viewing in “a plan view” means viewing an object from above.

### First Embodiment

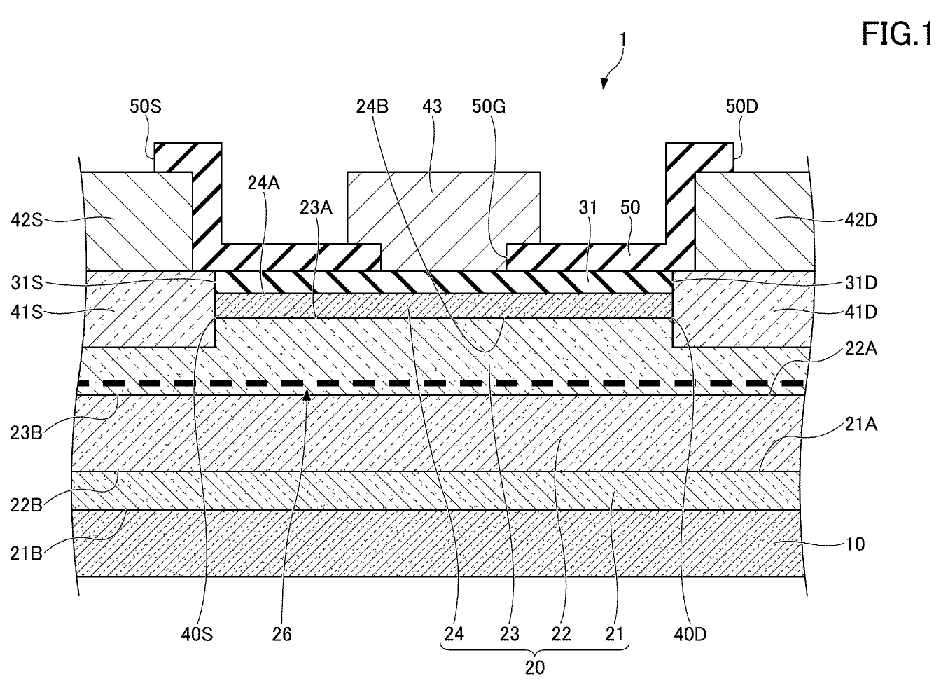

A first embodiment will be described. The first embodiment relates to a high electron mobility transistor (HEMT). FIG. 1 is a cross-sectional view showing the high electron mobility transistor according to the first embodiment.

As shown in FIG. 1, the HEMT 1 according to the first embodiment includes a substrate 10, a nitride semiconductor layer 20, a dielectric film 31, a passivation film 50, a regrown layer 41S, a regrown layer 41D, a gate electrode 43, a source electrode 42S, and a drain electrode 42D.

The substrate 10 is, for example, a semi-insulating silicon carbide (SiC) substrate. When the substrate 10 is the SiC substrate, the upper surface of the substrate 10 is a carbon (C)-polarity surface. When the surface of the substrate 10 is a C-polarity surface, the nitride semiconductor layer 20 can grow as crystals with a nitrogen (N)-polarity surface serving as the growth surface.

The nitride semiconductor layer 20 includes a buffer layer 21, a barrier layer 22, a channel layer 23, and a cap layer 24. The nitride semiconductor layer 20 may have a nucleation layer between the substrate 10 and the buffer layer 21. The barrier layer 22 is an example of the first barrier layer, and the cap layer 24 is an example of the second barrier layer.

The buffer layer 21 is located on the substrate 10. The buffer layer 21 is, for example, a gallium nitride (GaN) layer. The thickness of the buffer layer 21 is, for example, 10 nm or greater and 1,000 nm or less.

The barrier layer 22 is located on the buffer layer 21. The barrier layer 22 is, for example, an aluminum gallium nitride (AlGaN) layer. The thickness of the barrier layer 22 is, for example, 1 nm or greater and 50 nm or less. The composition of the barrier layer 22 is, for example, Al_{y}Ga_{1-y}N (0.15≤y≤0.55). When the composition of the barrier layer 22 is Al_{y}Ga_{1-y}N, the ratio of Al among Group III elements in the barrier layer 22 is y×100%. The barrier layer 22 contains an n-type impurity, that is, a donor impurity, and the conductivity type of the barrier layer 22 is n-type. The donor impurity is, for example, any one of silicon (Si), germanium (Ge), or oxygen (O). Instead of the AlGaN layer, a scandium aluminum nitride (ScAlN) layer, an indium aluminum nitride (InAlN) layer, or an indium aluminum gallium nitride (InAlGaN) layer may be used. In this case, the donor impurity may be other than silicon (Si), germanium (Ge), and oxygen (O). For example, the average impurity concentration in the barrier layer 22 is 1×10¹⁷ cm⁻³ or greater and 1×10²⁰ cm⁻³ or less.

The channel layer 23 is located on the barrier layer 22. The channel layer 23 is, for example, a GaN layer. The band gap of the channel layer 23 is less than the band gap of the barrier layer 22. The thickness of the channel layer 23 is, for example, 1 nm or greater and 50 nm or less. A crystal lattice strain occurs between the channel layer 23 and the barrier layer 22 due to differences in their lattice constants, and this strain induces piezo charges at the interface between them. As a result, a two-dimensional electron gas (2DEG) is emitted in the channel layer 23 in the vicinity of a surface of the channel layer 23 facing the barrier layer 22 to form a channel region 26. The conductivity type of the channel layer 23 is, for example, n-type or undoped type (i-type). Even when the channel layer 23 is undoped type (i-type), it can contain the above-specified donor impurity. The channel layer 23 has a first average impurity concentration of the doner impurity and a first band gap. For example, the first average impurity concentration is less than 1×10¹⁷ cm⁻³.

The cap layer 24 is located on the channel layer 23. The cap layer 24 is, for example, an AlGaN layer. The thickness of the cap layer 24 is, for example, 0.2 nm or greater and 10 nm or less. The composition of the cap layer 24 is, for example, AlₓGa₁₋ₓN (0.15≤x≤0.55). When the composition of the cap layer 24 is AlₓGa₁₋ₓN, the ratio of Al among Group III elements in the cap layer 24 is x×100%. The cap layer 24 contains an n-type impurity, i.e., a donor impurity, and the conductivity type of the cap layer 24 is n-type. For example, the cap layer 24 contains the same donor impurity as the doner impurity of the barrier layer 22 and the channel layer 23. The cap layer 24 has a second average impurity concentration higher than the first average impurity concentration and a second band gap greater than the first band gap. For example, the concentration of the impurity contained in the cap layer 24 is constant from a lower surface 24B to an upper surface 24A. For example, the second average impurity concentration of the donor impurity is 1×10 ¹⁷ cm⁻³ or greater and 1×10²⁰ cm⁻³ or less. The second average impurity concentration of the donor impurity may be 5×10¹⁷ cm⁻³ or greater and 1×10²⁰ cm⁻³ or less, and the second average impurity concentration of the donor impurity may be 1×10¹⁸ cm⁻³ or greater and 1×10²⁰ cm⁻³ or less. The impurity concentration in the vicinity of the lower surface 24B and the upper surface 24 A may be less than the above-specified constant value. As will be described later, by containing the donor impurity at the second average impurity concentration, the cap layer 24 supplies electrons to the channel layer 23 like the barrier layer 22 does. As a result, the electron concentration in the channel region 26 increases. Therefore, the cap layer 24 functions as a barrier layer for supplying electrons to the channel layer 23 like the barrier layer 22 does.

On the C-polarity surface of the SiC substrate, the buffer layer 21, the barrier layer 22, the channel layer 23, and the cap layer 24 grow as crystals with N-polarity surfaces serving as the growth surfaces. The buffer layer 21, the barrier layer 22, the channel layer 23, and the cap layer 24 are formed on the SiC substrate in this order. The direction in which each layer of the nitride semiconductor layer 20 is formed is also referred to as a layer lamination direction. In the layer lamination direction, the substrate 10 side with respect to the nitride semiconductor layer 20 is referred to as a lower side, a bottom, or the like, and the nitride semiconductor layer 20 side with respect to the substrate 10 is referred to as an upper side, a top, or the like. Upper surfaces 21A, 22A, 23A, and 24A of the buffer layer 21, the barrier layer 22, the channel layer 23, and the cap layer 24 formed along the layer lamination direction have N-polarity. Lower surfaces 21B, 22B, 23B, and 24B of the buffer layer 21, the barrier layer 22, the channel layer 23, and the cap layer 24 have metal polarity (gallium (Ga) polarity or aluminum (Al) polarity).

In the layer lamination direction, the lower surface 22B faces the upper surface 21A, the lower surface 23B faces the upper surface 22A, and the lower surface 24B faces the upper surface 23A. The upper surface 21A is a surface opposite to the lower surface 21B, the upper surface 22A is a surface opposite to the lower surface 22B, the upper surface 23A is a surface opposite to the lower surface 23B, and the upper surface 24A is a surface opposite to the lower surface 24B. The upper surface 22A is an example of the first main surface, the lower surface 23B is an example of the second main surface, the upper surface 23A is an example of the third main surface, the lower surface 24B is an example of the fourth main surface, and the upper surface 24A is an example of the fifth main surface.

A recess 40S for a source and a recess 40D for a drain are formed in the nitride semiconductor layer 20. In the layer lamination direction, the bottom of the recess 40S and the bottom of the recess 40D are closer to the lower surface of the nitride semiconductor layer 20 than the upper surface 23A of the channel layer 23 is. That is, the recess 40S and the recess 40D are formed to be deeper than the upper surface 23A of the channel layer 23. In the layer lamination direction, for example, the bottom of the recess 40S and the bottom of the recess 40D are located between the lower surface 23B of the channel layer 23 and the upper surface 23A of the channel layer 23. Note that the bottom of the recess 40S and the bottom of the recess 40D may be located on the lower surface 23B of the channel layer 23, or the recess 40S and the recess 40D may penetrate the channel layer 23, such that the bottom of the recess 40S and the bottom of the recess 40D may be located in the barrier layer 22. In addition, for example, the bottom of the recess 40S and the bottom of the recess 40D may be located at the same position as the position of the channel region 26 of the nitride semiconductor layer 20, or may be located between the channel region 26 and the lower surface 23B in the layer lamination direction.

The dielectric film 31 is located on the nitride semiconductor layer 20. The dielectric film 31 is in contact with the upper surface 24A of the cap layer 24. For example, the dielectric film 31 has a relative permittivity higher than the relative permittivity of silicon dioxide (SiO₂). The dielectric film 31 may be a high dielectric constant film. The dielectric film 31 is, for example, a silicon nitride (SiN) film. The dielectric film 31 may be a dielectric oxide film or a dielectric oxynitride film. The dielectric oxide film or the dielectric oxynitride film may contain at least one selected from the group consisting of hafnium (Hf), lanthanum (La), and zirconium (Zr). The dielectric oxide film or the dielectric oxynitride film may contain at least one selected from the group consisting of silicon (Si) and aluminum (Al). For example, the dielectric film 31 may be a hafnium silicate (HfSiO ₓ) film, a hafnium aluminate (HfAlOₓ) film, a hafnium silicon oxynitride (HfSiON) film, or a hafnium aluminum oxynitride (HfAlON) film. The thickness of the dielectric film 31 is, for example, 1 nm or greater and 30 nm or less. An opening 31S for a source and an opening 31D for a drain are formed in the dielectric film 31. The opening 31S leads to the recess 40S, and the opening 31D leads to the recess 40D.

The regrown layer 41S is present in the channel layer 23 or above the barrier layer 22 in the recess 40S. The regrown layer 41D is in the channel layer 23 or above the barrier layer 22 in the recess 40D. The bottom of the regrown layer 41S is in contact with the bottom of the recess 40S, and the bottom of the regrown layer 41D is in contact with the bottom of the recess 40D. The regrown layer 41S and the regrown layer 41D may be in contact with the channel region 26 or may be separated from the channel region 26. The regrown layer 41S and the regrown layer 41D are, for example, n-type GaN layers. The regrown layer 41S and the regrown layer 41D contain germanium (Ge) or silicon (Si) as an n-type impurity. The electrical resistance of the regrown layer 41S and the regrown layer 41D is lower than the electrical resistance of the channel layer 23. For example, the regrown layer 41S and the regrown layer 41D are formed by regrowing an n-type GaN layer after formation of the recess 40S and the recess 40D in the nitride semiconductor layer 20.

The source electrode 42S is located on the regrown layer 41S, and the drain electrode 42D is located on the regrown layer 41D. The source electrode 42S is in contact with the regrown layer 41S, and the drain electrode 42D is in contact with the regrown layer 41D. The source electrode 42S is in ohmic contact with the regrown layer 41S, and the drain electrode 42D is in ohmic contact with the regrown layer 41D.

The passivation film 50 covers the dielectric film 31, the regrown layer 41S, the regrown layer 41D, the source electrode 42S, and the drain electrode 42D. The passivation film 50 is, for example, the SiN film. The passivation film 50 has a thickness of, for example, 5 nm or greater and 50 nm or less in a uniform thickness part thereof that is on the dielectric film 31. An opening 50S for a source, an opening 50D for a drain, and an opening 50G for a gate are formed in the passivation film 50. The opening 50S reaches the source electrode 42S, and the opening 50D reaches the drain electrode 42D. The opening 50S exposes the source electrode 42S, and the opening 50D exposes the drain electrode 42D. In a plan view, the opening 50G is between the opening 50S and the opening 50D. The opening 50G reaches the dielectric film 31. The opening 50G exposes a part of the upper surface of the dielectric film 31 from the passivation film 50.

In a plan view, the gate electrode 43 is located between the source electrode 42S and the drain electrode 42D. The gate electrode 43 is located on the passivation film 50 and the dielectric film 31, and contacts the dielectric film 31 through the opening 50G. The gate electrode 43 may cover a part of the passivation film 50 in the vicinity of the opening 50G. For example, in a plan view, the gate electrode 43 may overlap the passivation film 50.

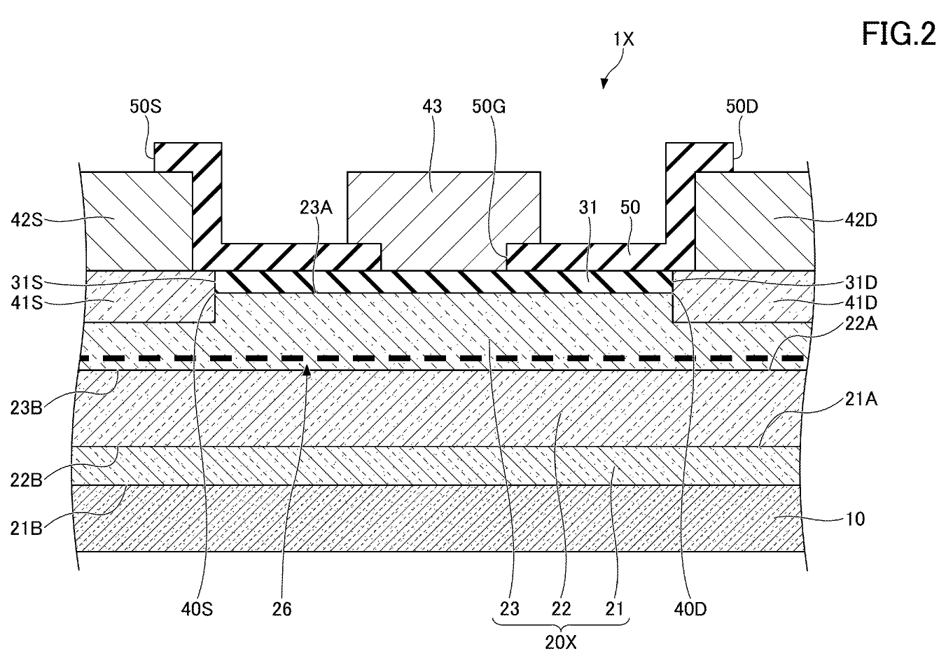

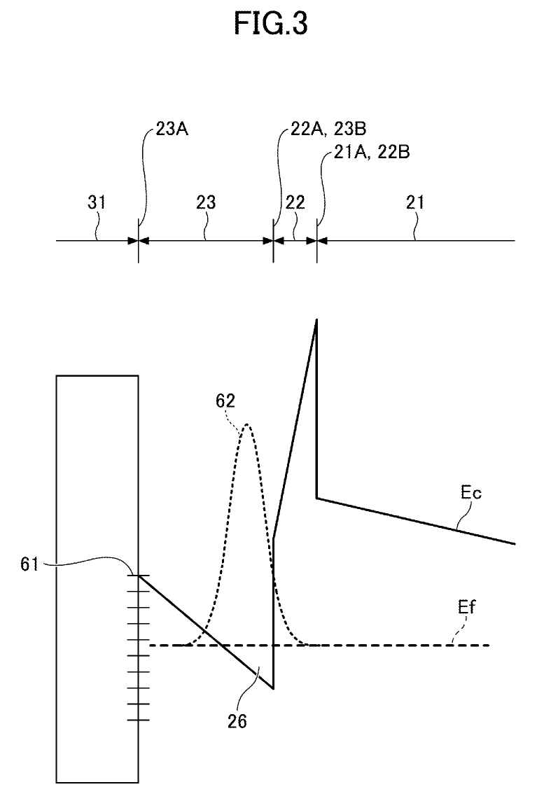

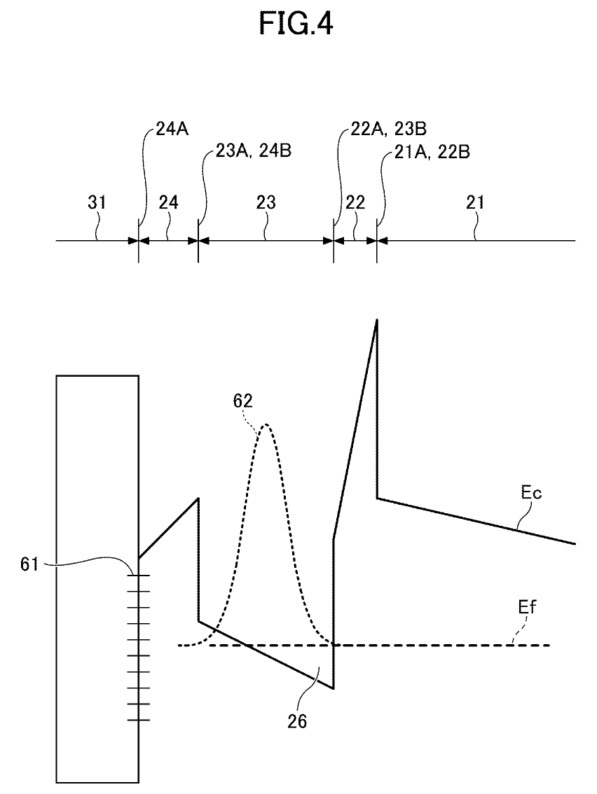

Next, the band structure of the HEMT 1 will be described in comparison with a reference example. FIG. 2 is a cross-sectional view showing a high electron mobility transistor according to the reference example. FIG. 3 is a diagram showing the band structure of the high electron mobility transistor according to the reference example. FIG. 4 is a diagram showing the band structure of the high electron mobility transistor according to the first embodiment. In FIGS. 3 and 4, Ef indicates the Fermi level in the nitride semiconductor layer 20.

A HEMT 1X according to the reference example includes a nitride semiconductor layer 20X instead of the nitride semiconductor layer 20, as shown in FIG. 2. The nitride semiconductor layer 20X includes a buffer layer 21, a barrier layer 22, and a channel layer 23, and does not include a cap layer 24. Other configurational particulars of the HEMT 1X are the same as the configurational particulars of the HEMT 1.

As shown in FIG. 3, in the HEMT 1X according to the reference example, an interface state 61 exists at the interface between the channel layer 23 and the dielectric film 31, and the conduction band minimum Ec becomes higher from the lower surface 23B to the upper surface 23A in the channel layer 23. Therefore, a part of a wave function 62 of the electrons in the channel region 26 penetrates the barrier layer 22 beyond the potential barrier at the lower surface 23B and the upper surface 22A. This means that a part of the 2DEG also exists in the barrier layer 22 quantum-mechanically microscopically. Therefore, impurity scattering of the electrons occurs due to electric effects from the impurity contained in the barrier layer 22. The impurity scattering of the electrons causes a decrease in the electron mobility.

On the other hand, in the HEMT 1 according to the first embodiment, the nitride semiconductor layer 20 includes the cap layer 24, and the cap layer 24 has the second average impurity concentration higher than the first average impurity concentration and the second band gap greater than the first band gap. Therefore, as shown in FIG. 4, the conduction band minimum Ec is higher in the cap layer 24 than in the channel layer 23, and becomes lower in the cap layer 24 from the lower surface 24B to the upper surface 24A. Thus, the nitride semiconductor layer 20 has a potential barrier (second potential barrier) at the lower surface 24B and the upper surface 23A in addition to the potential barrier (first potential barrier) at the lower surface 23B and the upper surface 22A. The band structure of the nitride semiconductor layer 20 includes a quantum well formed by the lower first potential barrier and the upper second potential barrier. Therefore, the slope of the conduction band minimum Ec with respect to the layer lamination direction between the first potential barrier and the second potential barrier is less than the slope in the channel layer 23 of the HEMT 1X according to the reference example. Therefore, it becomes easier for the wave function 62 of the electrons in the channel region 26 to become broader toward the upper surface 23A, and confinement of the electron wave function 62 is relaxed compared to the confinement in the HEMT 1X. This minimizes penetration of the electron wave function 62 into the barrier layer 22 beyond the first potential barrier, and reduces the impurity scattering of the electrons, thereby making it possible to improve the electron mobility as compared with the HEMT 1X. The first potential barrier and the second potential barrier may be, for example, 2 eV or higher.

For example, the following difference in electron mobility may occur between the HEMT 1 and the HEMT 1X. Here, it is assumed that the barrier layer 22 is an n-type Al_{0.4}Ga_{0.6}N layer, the channel layer 23 is an i-type GaN layer, and the cap layer 24 is an n-type AlGaN layer. It is also assumed that the barrier layer 22 has a thickness of 30 nm, the channel layer 23 has a thickness of 20 nm, and the electron concentration in the channel region 26 is 1.2×10¹³ cm⁻². It is also assumed that the distance between the gate electrode 43 and the regrown layer 41S in a plan view is 1 μm, and the distance between the gate electrode 43 and the regrown layer 41D in a plan view is 3 μm. Under these conditions, for example, the electron mobility in the HEMT 1X is approximately 1,600 cm²/Vs, while the electron mobility in the HEMT 1 is approximately 1,850 cm²/Vs. Thus, the electron mobility in the HEMT 1 is approximately 1.16 times that in the HEMT 1X.

Further, in the HEMT 1, since the conduction band minimum Ec is higher in the cap layer 24 than in the channel layer 23, it is possible to make electrons less likely to be trapped in the interface state 61. Therefore, occurrence of current collapse or the like associated with electron trapping can be inhibited.

When the conductivity type of the channel layer 23 is undoped type (i-type), impurity scattering in the channel layer 23 can be prevented. When the conductivity type of the channel layer 23 is undoped type (i-type), the first average impurity concentration is less than 1×10¹⁷ cm⁻³.

When the barrier layer 22 contains AlGaN and the channel layer 23 contains GaN, it is easy to epitaxially grow the barrier layer 22 and the channel layer 23 by a Metal Organic Chemical Vapor Deposition (MOCVD) method and the like, and to achieve stable characteristics. When the cap layer 24 contains AlGaN, it is easy to epitaxially grow the cap layer 24, and to achieve stable characteristics.

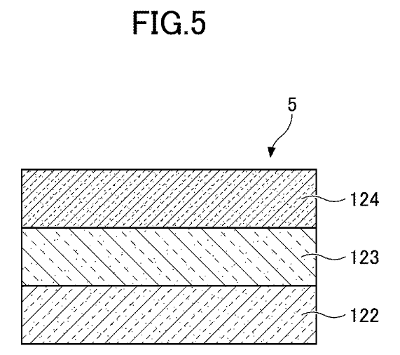

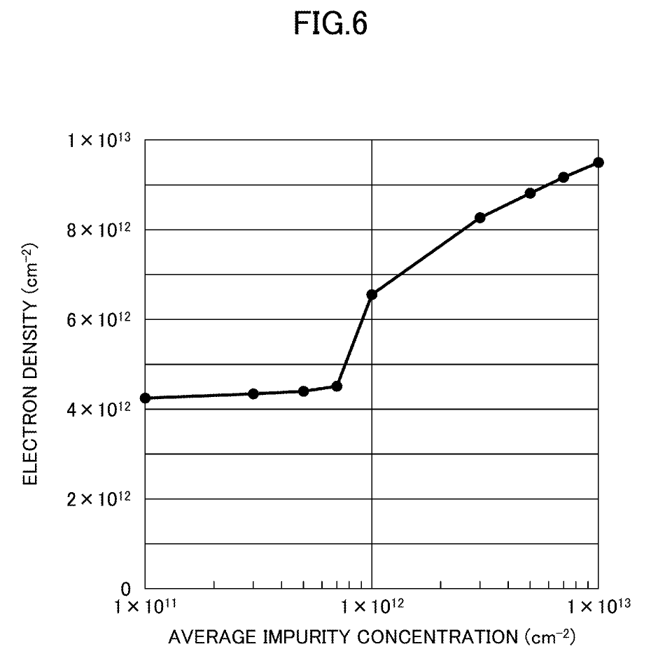

Now, the results of a simulation of the first embodiment will be described. FIG. 5 is a cross-sectional view showing a model used in the simulation. FIG. 6 is a diagram showing the results of the simulation.

As shown in FIG. 5, a model 5 includes a barrier layer 122, a channel layer 123 on the barrier layer 122, and a cap layer 124 on the channel layer 123. The barrier layer 122 is an n-type AlGaN layer, the channel layer 123 is an i-type GaN layer, and the cap layer 124 is an n-type AlGaN layer. The thickness of the cap layer 124 is 10 nm. In FIG. 6, the horizontal axis indicates the average impurity concentration of the n-type impurity in the cap layer 124, and the vertical axis indicates the electron density in the channel region in the channel layer 123. As shown in FIG. 6, when the average impurity concentration is 1×10¹² cm⁻² or greater, the increase in the electron density accompanying the increase in the average impurity concentration is remarkable. The average impurity concentration on the horizontal axis in FIG. 6 is the sheet average impurity concentration in the cap layer 124 having a thickness of 10 nm. When converted into the average impurity concentration per volume, a sheet average impurity concentration of 1×10 ¹² cm⁻² amounts to an average impurity concentration per volume of 1×10¹⁸ cm⁻³. An increase in the electron density is observed, starting from a sheet average impurity concentration of 5×10¹¹ cm⁻² (an average impurity concentration per volume of 5×10¹⁷ cm⁻³) on the horizontal axis.

The concentration of the impurity contained in the cap layer 24 does not need to be constant from the lower surface 24B to the upper surface 24A. When the impurity concentration at the upper surface 24A is lower than the impurity concentration at the lower surface 24B, gate leakage can be reduced. The concentration of the impurity contained in the cap layer 24 may continuously decrease or may gradually and discontinuously decrease from the lower surface 24B to the upper surface 24A. The impurity concentration at the upper surface 24A may be equal to or less than 1/2, equal to or less than 1/5, or equal to or less than 1/10 the impurity concentration at the lower surface 24B.

### Second Embodiment

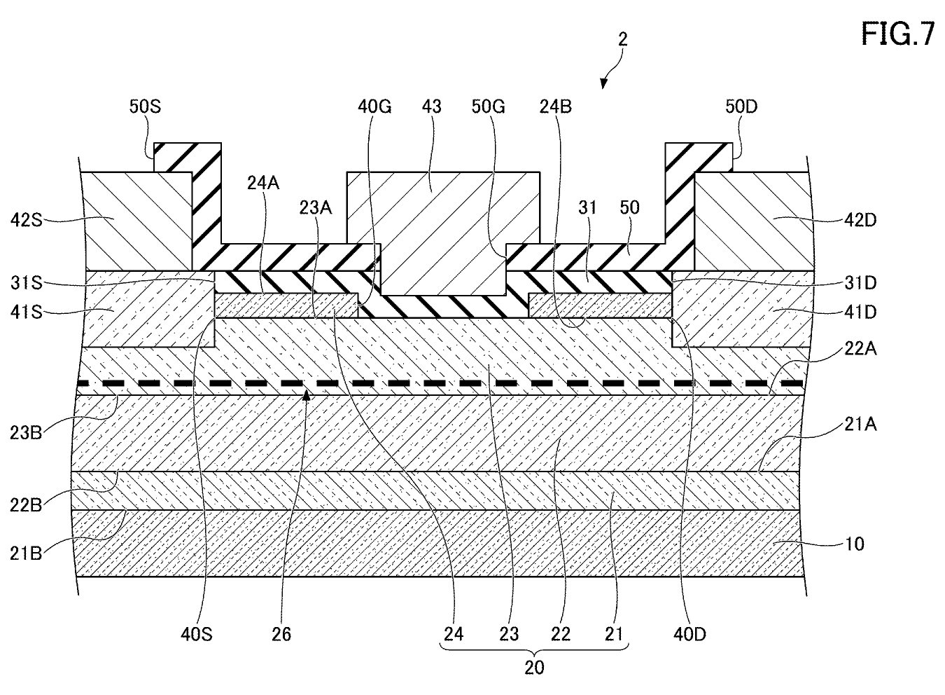

A second embodiment will be described. The second embodiment differs from the first embodiment in the configuration around the gate electrode. FIG. 7 is a cross-sectional view showing a high electron mobility transistor according to the second embodiment.

In an HEMT 2 according to the second embodiment, as shown in FIG. 7, a recess for a gate (second gate opening) 40G is formed in the cap layer 24. The recess 40G is located between the recess 40S and the recess 40D, and an opening (first gate opening) 50G is located within the recess 40G in a plan view. For example, the recess 40G penetrates the cap layer 24. The channel layer 23 is exposed through the recess 40G. A part of the dielectric film 31 is located in the recess 40G, and the dielectric film 31 contacts the channel layer 23. The dielectric film 31 covers a part of the upper surface 23A of the channel layer 23 exposed through the recess 40G and the upper surface 24A of the cap layer 24. The opening 50G exposes a part of the dielectric film 31 from the passivation film 50. The passivation film 50 covers the upper surface of the dielectric film 31. The gate electrode 43 covers the dielectric film 31 exposed through the opening 50G and part of the upper surface of the passivation film 50. For example, the gate electrode 43 may overlap the passivation film 50 around the opening 50G in a plan view.

Other configurational particulars of the second embodiment are the same as those of the first embodiment.

Like the first embodiment, the second embodiment can improve the electron mobility in the channel region 26. Further, in the HEMT 1, since the cap layer 24 including an n-type impurity is located between the lower end of the gate electrode 43 and the channel region 26, the threshold voltage is deeper than that in the HEMT 1X. On the other hand, in the HEMT 2, since the recess 40G is formed in the cap layer 24, the distance between the gate electrode 43 and the channel region 26 is shortened. This prevents the threshold voltage from becoming excessively deep. When the threshold voltage becomes deep, and becomes, for example, a negative value, it is necessary to make the gate voltage lower than this threshold voltage, which makes it difficult to turn off the drain current of the HEMT 1.

Note that it is not necessary that the recess 40G penetrates the cap layer 24. Even when the recess 40G does not penetrate the cap layer 24, the recess 40G being formed prevents the threshold voltage from becoming excessively deep. In this case, the bottom surface of the recess 40G is located between the lower surface 24B and the upper surface 24A of the cap layer 24 in the layer lamination direction.

### Third Embodiment

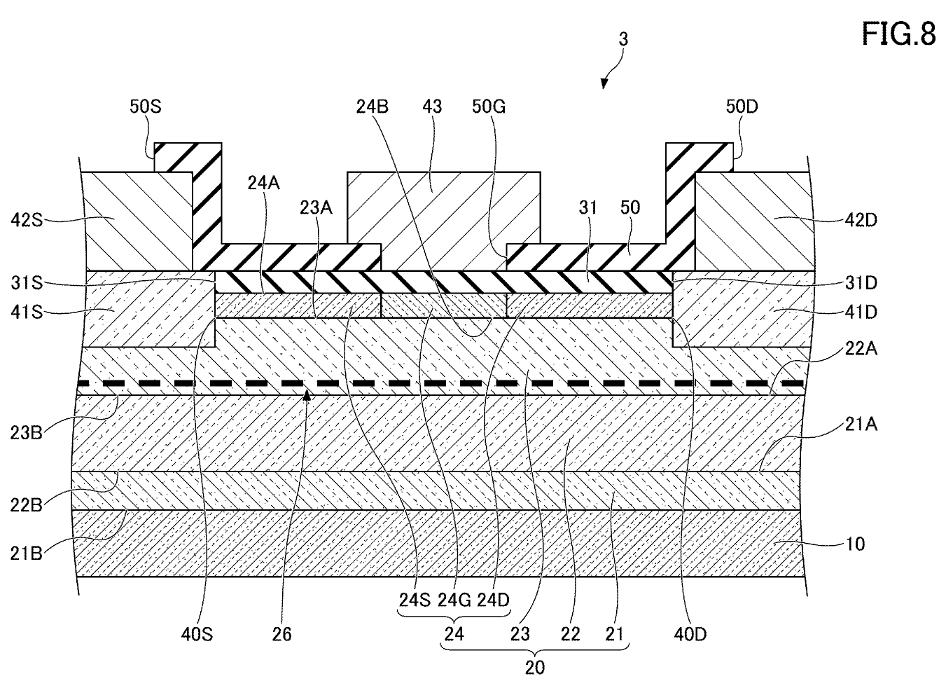

A third embodiment will be described. The third embodiment differs from the first embodiment in the configuration of the cap layer. FIG. 8 is a cross-sectional view showing a high electron mobility transistor according to the third embodiment.

In an HEMT 3 according to the third embodiment, as shown in FIG. 8, the cap layer 24 includes a first region 24G, a second region 24S, and a third region 24D between the recess 40S and the recess 40D. The first region 24G overlaps the gate electrode 43 in a plan view. For example, the first region 24G coincides with a part of the gate electrode 43 that is within the opening 50G in a plan view. The second region 24S is located between the first region 24G and the regrown layer 41S. The third region 24D is located between the first region 24G and the regrown layer 41D. The first region 24G has a third average impurity concentration, the second region 24S has a fourth average impurity concentration higher than the third average impurity concentration, and the third region 24D has a fifth average impurity concentration higher than the third average impurity concentration. That is, the third average impurity concentration is lower than the fourth average impurity concentration and the fifth average impurity concentration.

Other configurational particulars of the third embodiment are the same as those of the first embodiment.

Like the first embodiment, the third embodiment can also improve the electron mobility. Further, in the HEMT 3, since the third average impurity concentration is lower than the fourth average impurity concentration and the fifth average impurity concentration, the threshold voltage can be prevented from becoming excessively deep as in the HEMT 2.

The concentration of electrons in the channel region 26 is increased by the ratio of Al among Group III elements contained in the cap layer 24 being 15 at% or greater and 55 at% or less, and the second average impurity concentration being 1×10 ¹⁷ cm⁻³ or greater. Further, the second average impurity concentration being 1×10²⁰ cm⁻³ or less can prevent the threshold voltage from becoming excessively deep. The second average impurity concentration may be 5×10¹⁷ cm⁻³ or greater and 5×10¹⁹ cm⁻³ or less, or may be 1×10¹⁸ cm⁻³ or greater and 1×10¹⁹ cm⁻³ or less.

The ratio of Al among Group III elements in the cap layer 24 can be measured by X-Ray Diffraction (XRD) or Energy Dispersive X-ray spectroscopy (EDX).

The impurity concentration in the channel layer 23 and the impurity concentration in the cap layer 24 can be measured by Secondary Ion Mass Spectrometry (SIMS). In the present disclosure, the average impurity concentration in a layer is an average value of the impurity concentrations measured from the lower surface to the upper surface of the layer along the layer lamination direction.

The sum of the thickness of the channel layer 23 and the thickness of the cap layer 24 is, for example, 25 nm or less. When the sum of the thickness of the channel layer 23 and the thickness of the cap layer 24 is 25 nm or less, it is possible to turn off the drain current without excessively lowering the gate voltage by, for example, lowering it to a negative value and the like.

As described above, when the band structure of the nitride semiconductor layer 20 includes a quantum well having the first potential barrier and the second potential barrier, and the thickness of the channel layer is thin and, for example, 5 nm or less, the wave function of the electrons in the channel region 26 is weakly confined in the quantum well, and the tail ends of the wave function penetrate the barrier layer 22 and the cap layer 24, resulting in reduction of the electron mobility due to the impurity scattering by the donor impurity. For this reason, the thickness of the channel layer 23 is preferably 10 nm or greater.

Although the embodiments have been described in detail above, the present disclosure is not limited to particular embodiments, and various modifications and changes are applicable within the scope described in the claims.

What is claimed is:

1. A high electron mobility transistor, comprising:
a first barrier layer having a first main surface and containing an impurity;
a channel layer having a second main surface facing the first main surface and a third main surface opposite to the second main surface; and
a second barrier layer having a fourth main surface facing the third main surface,
wherein the first main surface has a nitrogen polarity,
the channel layer has a first average impurity concentration of the impurity and a first band gap, and
the second barrier layer has a second average impurity concentration of the impurity higher than the first average impurity concentration in the channel layer, and has a second band gap greater than the first band gap of the channel layer.

2. The high electron mobility transistor according to claim 1,
wherein the first barrier layer contains aluminum gallium nitride, and
the channel layer contains gallium nitride.

3. The high electron mobility transistor according to claim 2,
wherein the second barrier layer contains aluminum gallium nitride.

4. The high electron mobility transistor according to claim 3,
wherein a ratio of aluminum among Group III elements contained in the second barrier layer is 15 at% or greater and 55 at% or less, and
the second average impurity concentration is 1×10¹⁷ cm⁻³ or greater and 1×10²⁰ cm⁻³ or less.

5. The high electron mobility transistor according to claim 1,
wherein the first average impurity concentration is less than 1×10¹⁷ cm⁻³.

6. The high electron mobility transistor according to claim 1,
wherein the second barrier layer has a fifth main surface opposite to the fourth main surface, and
an impurity concentration of the impurity in the fifth main surface is lower than an impurity concentration of the impurity in the fourth main surface.

7. The high electron mobility transistor according to claim 1,
wherein the high electron mobility transistor further includes a source electrode, a gate electrode, and a drain electrode provided above the second barrier layer, and
a recess is formed in the second barrier layer such that the recess overlaps the gate electrode in a plan view perpendicular to the first main surface.

8. The high electron mobility transistor according to claim 1,
wherein the high electron mobility transistor further includes a source electrode, a gate electrode, and a drain electrode above the second barrier layer,
the second barrier layer includes a first region overlapping the gate electrode in a plan view, a second region closer to the source electrode than the first region is, and a third region closer to the drain electrode than the first region is,
the first region has a third average impurity concentration,
the second region has a fourth average impurity concentration higher than the third average impurity concentration, and
the third region has a fifth average impurity concentration higher than the third average impurity concentration.

9. The high electron mobility transistor according to claim 1,
wherein the high electron mobility transistor has a band structure in which a quantum well formed by a first potential barrier and a second potential barrier is located between the first barrier layer and the second barrier layer in a layer lamination direction.
